(19) United States
(12) Patent Application Publication
(10) Pub. No.: US 2024/0347672 A1
(43) Pub. Date: Oct. 17, 2024

(54) LIGHT EMITTING DIODE AND LIGHT EMITTING DEVICE COMPRISING SAME

(71) Applicant: XIAMEN SAN'AN OPTOELECTRONICS CO., LTD., Xiamen (CN)

(72) Inventors: PoYang CHANG, Xiamen (CN); Fanwei LIN, Xiamen (CN); Hsintai LIN, Xiamen (CN); Chung-Ying CHANG, Xiamen (CN)

(21) Appl. No.: 18/751,813

(22) Filed: Jun. 24, 2024

Related U.S. Application Data
(63) Continuation-in-part of application No. PCT/CN2021/143945, filed on Dec. 31, 2021.

(51) Int. Cl. H01L 33/22; H01L 33/32; H01L 33/46; H01L 33/52

(52) U.S. Cl. CPC H01L 33/22; H01L 33/325; H01L 33/46; H01L 33/52

(57) ABSTRACT

A light-emitting diode includes an epitaxial structure, a first electrical connection structure, a second electrical connection structure, a first insulation layer, and a second insulation layer. The epitaxial structure has a first surface, a second surface opposite to the first surface, and a side boundary surface formed between the first surface and the second surface, and includes a first type semiconductor layer, an active layer and a second type semiconductor layer that are sequentially arranged. The epitaxial structure is formed with at least one recess on the second surface. The at least one recess is formed near a periphery of the side boundary surface. The first electrical connection structure has a protrusion extending through the at least one recess, and electrically connected to the first type semiconductor layer. At least a portion of the side boundary surface positioned above the at least one recess has a roughened surface.

### CROSS-REFERENCE TO RELATED APPLICATION

This application is a continuation-in-part (CIP) of International Application No. PCT/CN2021/143945, filed on Dec. 31, 2021, the entire disclosure of which is incorporated by reference herein.

### FIELD

The disclosure relates to a light-emitting device, and more particularly to a light-emitting diode and a light-emitting device having the same.

### BACKGROUND

In a conventional vertical type light-emitting diode (LED), the n-type conductive hole in the light-emitting region is used for achieving functions of current spreading and lowering currents. However, when an area of the n-type conductive hole region increases, an area of the light-emitting region decreases (i.e., a roughened surface of the light-emitting region), thereby decreasing the brightness of the LED. When a size of the LED becomes smaller, the process window for manufacturing the n-type conductive hole region is limited due to limitation of the manufacturing platform, which results in manufacturing difficulties. Hence, there is room for improvement.

### SUMMARY

Therefore, an object of the disclosure is to provide a light-emitting diode and a light-emitting device having the same that can alleviate at least one of the drawbacks of the prior art.

According to one aspect of the disclosure, the light-emitting diode includes an epitaxial structure, a first electrical connection structure, a second electrical connection structure, a first insulation layer, and a second insulation layer. The epitaxial structure has a first surface, a second surface opposite to the first surface, and a side boundary surface formed between the first surface and the second surface, and includes a first type semiconductor layer, an active layer and a second type semiconductor layer that are sequentially arranged in a direction from the first surface to the second surface. The active layer is configured for emitting light. The first electrical connection structure is electrically connected to the first type semiconductor layer, and includes a reflective metal material. The second electrical connection structure is electrically connected to the second type semiconductor layer. The second insulation layer is disposed between the first electrical connection structure and the second electrical connection structure. The first electrical connection structure and the second electrical connection structure are electrically isolated from each other by the second insulation layer. The epitaxial structure is formed with at least one recess on the second surface. The at least one recess extends through the second type semiconductor layer, the active layer and a portion of the first type semiconductor layer. The at least one recess is formed near a periphery of the side boundary surface. The first insulation layer is disposed in the recess and extends to the second surface. The first electrical connection structure has a protrusion extending through the at least one recess, and electrically connected to the first type semiconductor layer. At least a portion of the side boundary surface positioned above the at least one recess has a roughened surface.

According to another aspect of the disclosure, the light-emitting device includes a packaging substrate, an encapsulation material, and the above-mentioned light-emitting diode. The light-emitting diode is mounted on the packaging substrate and covered by the encapsulation material.

### BRIEF DESCRIPTION OF THE DRAWINGS

Other features and advantages of the disclosure will become apparent in the following detailed description of the embodiment(s) with reference to the accompanying drawings. It is noted that various features may not be drawn to scale.

FIG. 1 is a schematic sectional view illustrating a first embodiment according to the disclosure.

FIG. 2 is a schematic top view of the first embodiment, illustrating a recess being continuously formed in an epitaxial structure of the first embodiment.

FIG. 3 is a schematic top view of the first embodiment, illustrating a recess being not continuously formed in the epitaxial structure of the first embodiment.

FIG. 4 is a schematic sectional view of a second embodiment of the disclosure.

FIG. 5 is a schematic sectional view of a third embodiment according to the disclosure.

FIG. 6 shows a variation of the third embodiment of the disclosure.

FIG. 7 is a schematic sectional view of a fourth embodiment according to the disclosure.

FIG. 8 shows a fifth embodiment.

FIG. 9 is a schematic sectional view of a sixth embodiment according to the disclosure.

FIG. 10 shows a seventh embodiment.

FIG. 11 is a schematic sectional view of an eighth of the disclosure.

### DETAILED DESCRIPTION

Before the disclosure is described in greater detail, it should be noted that where considered appropriate, reference numerals or terminal portions of reference numerals have been repeated among the figures to indicate corresponding or analogous elements, which may optionally have similar characteristics.

It should be noted herein that for clarity of description, spatially relative terms such as “top,” “bottom,” “upper,” “lower,” “on,” “above,” “over,” “downwardly,” “upwardly” and the like may be used throughout the disclosure while making reference to the features as illustrated in the drawings. The features may be oriented differently (e.g., rotated 90 degrees or at other orientations) and the spatially relative terms used herein may be interpreted accordingly.

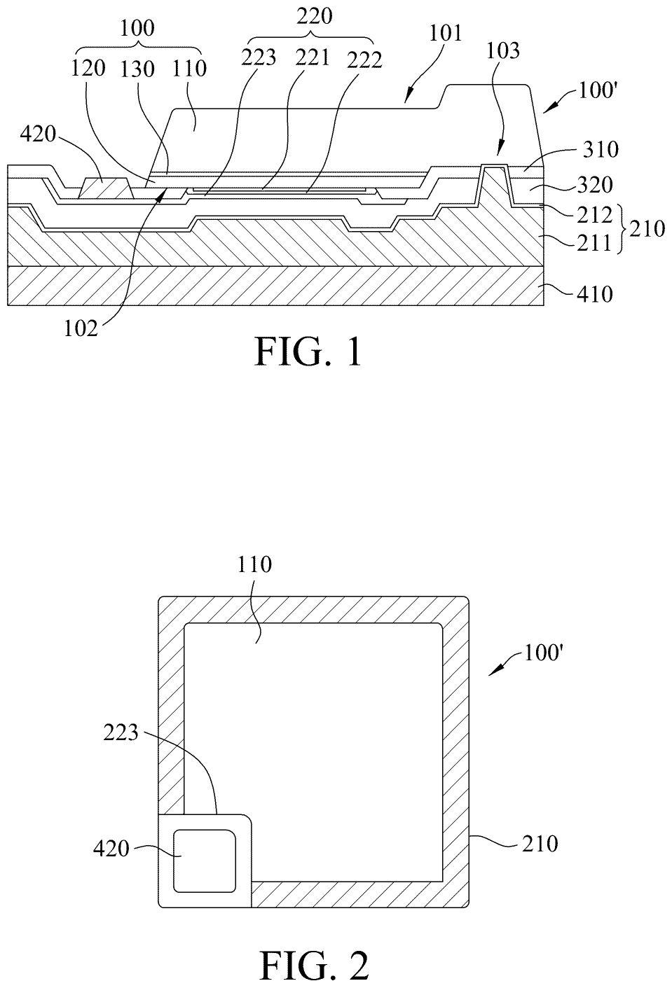

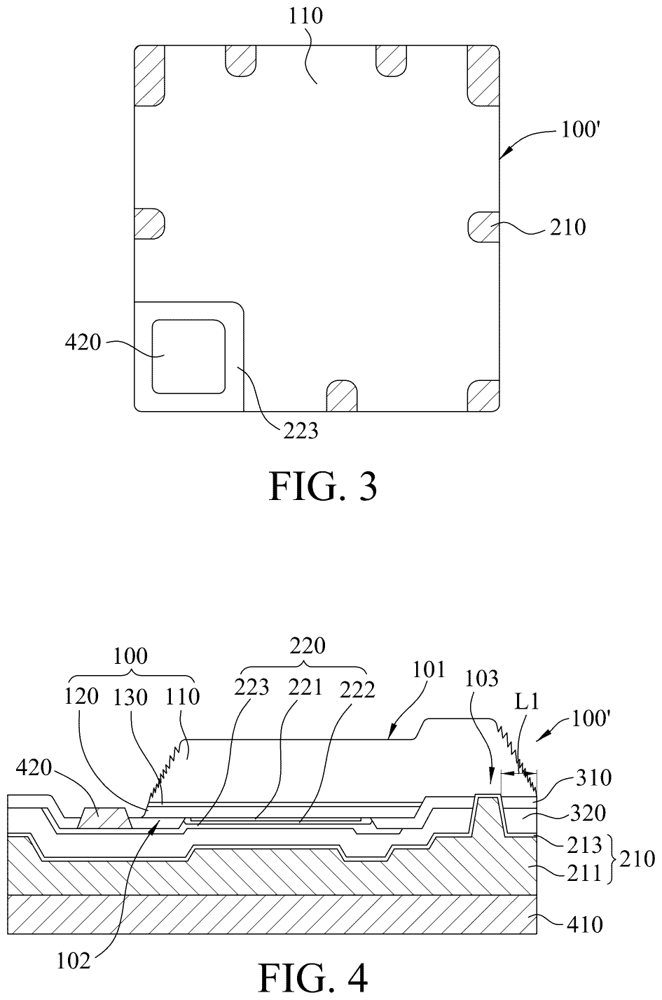

Referring to FIGS. 1 to 3, an unfinished product of a first embodiment of a light-emitting diode (LED) according to the disclosure includes an epitaxial structure 100, a first electrical connection structure 210, a second electrical connection structure 220, a first insulation layer 310, and a second insulation layer 320. The epitaxial structure 100 has a first surface 101, a second surface 102 opposite to the first surface 101, and a side boundary surface 100′ formed between the first surface 101 and the second surface 102, and includes a first type semiconductor layer 110, an active layer 130 and a second type semiconductor layer 120 sequentially arranged in a direction from the first surface 101 to the second surface 102. The active layer 130 has a quantum well structure and is configured for emitting light. The first electrical connection structure 210 is electrically connected to the first type semiconductor layer 110, and includes a reflective metal material. When the light exits from a light-exiting surface (i.e., the first surface 101 in this embodiment), the first electrical connection structure 210 is reflective due to the reflective metal material therein, so as to reflect the light toward the first surface 101. The second electrical connection structure 220 is electrically connected to the second type semiconductor layer 120, and may also include a 15 reflective metal material. The second insulation layer 320 is disposed between the first electrical connection structure 210 and the second electrical connection structure 220. The first electrical connection structure 210 and the second electrical connection structure 220 are electrically isolated from each other by the first insulation layer 310 and/or the second insulation layer 320. The epitaxial structure 100 is formed with at least one recess 103 on the second surface 102. In some embodiments, the at least one recess 103 is situated along a die cutting channel of the LED. The at least one recess 103 extends through the second type semiconductor layer 120, the active layer 130 and a portion of the first type semiconductor layer 110, and is formed near a periphery of the side boundary surface 100′. Specifically, in the first embodiment, the at least one recess 103 is opened at the side boundary surface 100′. The first insulation layer 310 is disposed in the recess 103 and extends to the second surface 102. The first electrical connection structure 210 has a protrusion extending through the at least one recess 103 and electrically connected to the first type semiconductor layer 110. It should be noted that, in FIG. 2 and FIG. 3, a portion of the first electrical connection structure 210 corresponding in position to the at least one recess 103 is visible due to high light transmittance of the first type semiconductor layer 110. In some embodiments, a portion of the first insulation layer 310 covers the at least one recess 103 and is formed with an insulation hole to expose the first type semiconductor layer 110 and let the protrusion of the first electrical connection structure 210 to extend therethrough for electrically connecting to the first type semiconductor layer (110); in addition, the first insulation layer 310 partially covers and contacts the second surface 102, and uncovers a portion of the second type semiconductor layer 120 for electrically connecting to the second electrical connection structure 220.

The at least one recess 103 may be continuously formed or not continuously formed along the side boundary surface 100′. When a dimension of one of lateral sides of the LED is smaller than 600 μm (eg., smaller than 500 μm), the at least one recess 103 is continuously formed along the side boundary surface 100′, and when the dimension is not smaller than 600 μm (e.g., not smaller than 500 μm), the at least one recess 103 is not continuously formed along the side boundary surface 100′. When the at least one recess 103 is not continuously formed along the side boundary surface 100′, the at least one recess 103 includes a plurality of spaced apart recesses 103, and the side boundary surface 100′ between the recesses 103 includes the first type semiconductor layer 110, the active layer 130, and the second type semiconductor layer 120. In some embodiments, when the epitaxial structure 100 is subjected to a thinning process, an additional height may be provided on the first surface 101 of the first type semiconductor layer 110 positioned above the at least one recess 103 by a photolithographic patterning technique in order to avoid excessive thinning of the first type semiconductor layer 110 above the at least one recess 103, which may cause occurrence of abnormal current spreading.

In some embodiments, a conductive substrate or an insulation substrate is disposed on a side of the second surface 102 opposite to the first surface 101. In this embodiment, a conductive substrate is disposed on the side of the second surface 102 opposite to the first surface 101 and is a first electrode 410. A material of the conductive substrate includes silicon, copper, molybdenum or tungsten, and a material of the insulation substrate may be sapphire or ceramic. The first electrical connection structure 210 includes a metal bonding layer 211 and a contact layer 212. The first electrode 410 is electrically connected to the contact layer 212 through the metal bonding layer 211. Specifically, the first electrode 410 is electrically connected to the first electrical connection structure 210, and a second electrode 420 is disposed on a surface of the second electrical connection structure 220 opposite to the first electrical connection structure 210. The first and second electrodes 410, 420 are configured for being connected to an external electrical circuit.

In this embodiment, the second electrical connection structure 220 includes a transparent conductive layer 221 contacting the epitaxial structure 100, a second reflective layer 222, and a metal connection layer 223. In some embodiments, one of or both of the first electrical connection structure 210 and the second electrical connection structure 220 include(s) the transparent conductive layer 221 configured for ohmic contact.

Referring to FIG. 4, in a second embodiment, the first electrical connection structure 210 includes a first reflective layer 213 instead of the contact layer 212. A reflective metal material of the first reflective layer 213 is silver, aluminum, gold, titanium, or rhodium. A distance (L1) between the protrusion of the first electrical connection structure 210 that extends into the recess 103 and the side boundary surface 100′ is not greater than 8 μm; in other words, the protrusion of the first electrical connection structure 210 is spaced apart from the side boundary surface 100′ by the distance not greater than 8 μm. In addition, a portion of the side boundary surface 100′ positioned above the recess 103 is roughened to have an average particle size ranging from 0.1 μm to 2 μm. In some embodiments, the average particle size ranges from 0.05 μm to 2 μm. By virtue of the roughened particles on the side boundary surface 100′, light from the external environment will not emit toward the first reflective layer 213. The side boundary surface 100′ is inclined to an imaginary plane, which is perpendicular to the second surface 102, by an angle that ranges from 20 degrees to 60 degrees. In this embodiment, the side boundary surface 100′ is roughened by a single-stepped wet etching with KOH solution or NaOH solution (i.e., the alkaline etching solution that is relatively mild). The first type semiconductor layer 110, the active layer 130 and/or the second type semiconductor layer 120 are made of a GaN-based material. A portion of the side boundary surface 100′ where the recess 103 exists includes the first type semiconductor layer 110, the first type semiconductor layer 110 is an n-type semiconductor layer doped with silicon, and the second type semiconductor layer 120 is a p-type semiconductor layer doped with magnesium. The first type semiconductor layer 110 has a growth temperature that is higher than a growth temperature of the second type semiconductor layer 120. The first type semiconductor layer 110 grows faster than the second type semiconductor layer 120. In the etching process of the epitaxial structure 100, an etching speed of the first type semiconductor layer 110 is faster than an etching speed of the second type semiconductor layer 120; thus, by controlling etching conditions for surface roughening, larger roughened particle sizes may be produced. In this embodiment, the roughened particle structures may have an irregular roughened shape, a hemispherical shape, a conical shape, a conical-like shape, etc.

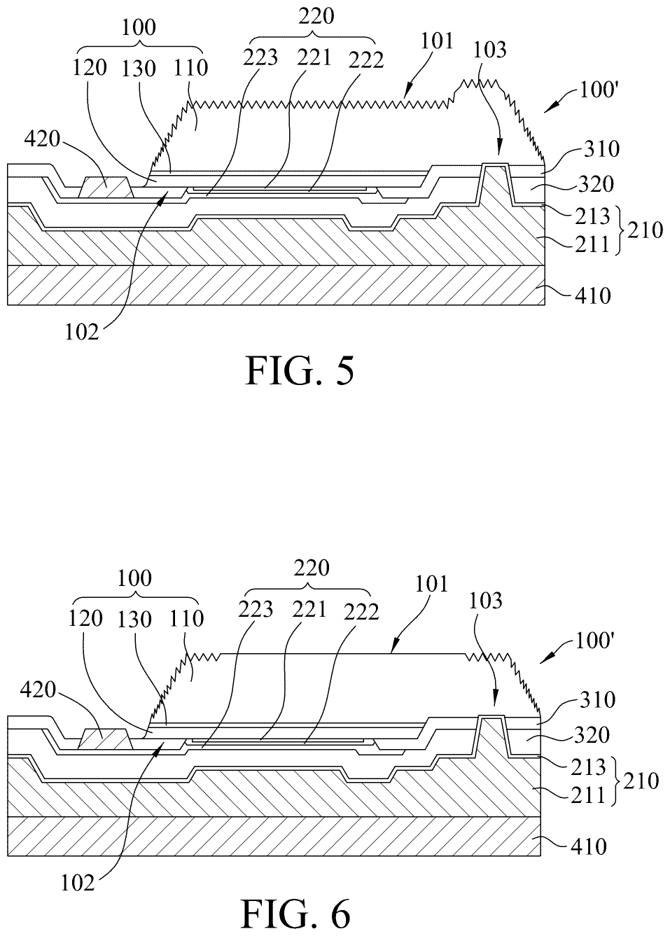

Referring to FIGS. 5 and 6, a third embodiment of the LED is illustrated. In the third embodiment, the first surface 101 is the light-exiting surface, and in addition to the side boundary surface 100′, a portion of the first surface 101 is also roughened. Specifically, light emits from the active layer 130, and exits from the first surface 101 to the external environment. In some embodiments, a portion of the first surface 101 positioned straightforwardly above the recess 103 is roughened or patterned; in other embodiment, another portion of the first surface 101 is also roughened. The recess 103 has a cross section that is parallel to the second surface 102, and an area of the portion of the first surface 101 that is roughened or patterned is 120% of an area of the cross section of the recess 103, so as to ensure that light generated from a photolithography process can be shielded efficiently from reaching the first reflective layer 213. A roughness of the first surface 101 is not smaller than 0.5 μm, and may range from 0.5 μm to 2 μm.

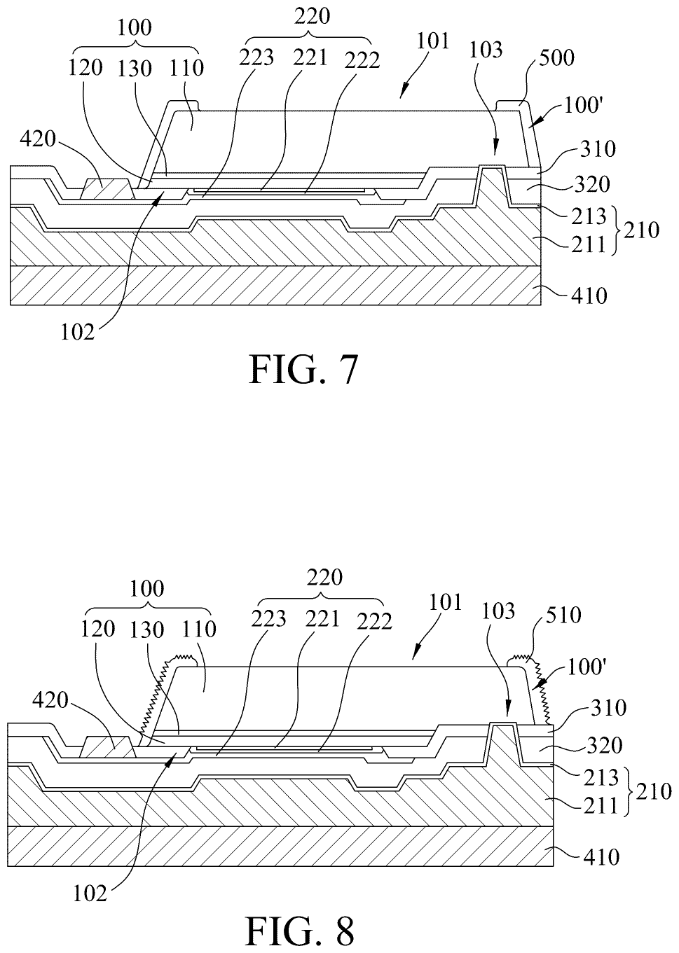

Referring to FIG. 7, a fourth embodiment of the LED that differs from the first embodiment in that it additionally includes a light-shielding layer 500 disposed on a portion of the first surface 101 above the recess 103 and a portion of the side boundary surface 100′ above the recess 103, and the light-shielding layer 500 may be a reflector or an opaque layer. The light-shielding layer 500 is configured for shielding light from entering the epitaxial structure 100 during the photolithography process of the LED. In some embodiments, the light-shielding 500 may be a distributed Bragg reflector (DBR) layer or a selective light transmission layer. In this embodiment, the light-shielding layer 500 is made of an insulation material, and extends along the side boundary surface 100′ from the first surface 101 in a direction toward the first electrode 410.

Referring to FIG. 8, a fifth embodiment that differs from the first embodiment in that a roughened covering layer 510 is disposed on the first surface 101 and the side boundary surface 100′ and is roughened to have the roughened surface. The roughened covering layer 510 may be a roughened insulation layer, and may be made of silicon dioxide, aluminum oxide, silicon nitride or titanium oxide. The roughened covering layer 510 is used for shielding light from entering the epitaxial structure 100 during the photolithography process of the LED. In this embodiment, the roughened covering layer 510 extends along the side boundary surface 100′ from the first surface 101 in a direction toward the second surface 102.

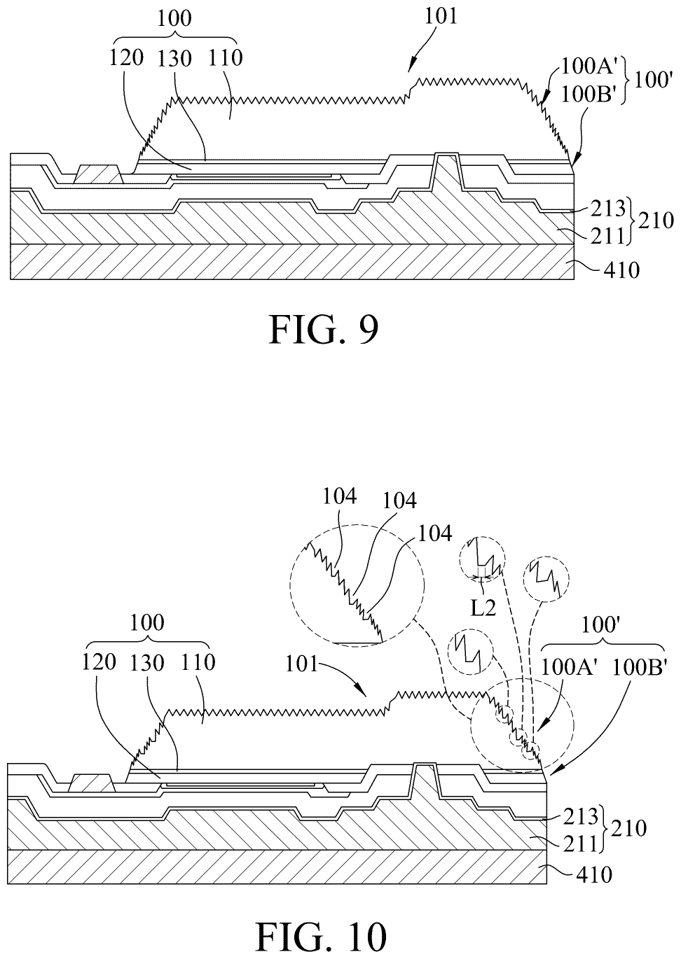

Referring to FIG. 9, in a sixth embodiment of the LED, the side boundary surface 100′ is formed with a first side boundary surface 100A′ and a second side boundary surface 100B′. The first side boundary surface 100A′ includes a sloping side of the first type semiconductor layer 110; the sloping side may have a constant or non-constant sloping angle. The second side boundary surface 100B′ includes a sloping side of the second type semiconductor layer 120; the sloping side may have a constant sloping or non-sloping angle. The roughness of the first side boundary surface 100A′ is not smaller than that of the second side boundary surface 100B′; this arrangement can enhance a small angle radiating effect. The first side boundary surface 100A′ is higher than the second side boundary surface 100B′; that is to say, the first side boundary surface 100A′ is more adjacent to the first surface 101 than the second side boundary surface 100B′. The first side boundary surface 100A′ and/or the second side boundary surface 100B′ are inclined to an imaginary plane perpendicular to the second surface 102 (i.e., a vertical plane) by an angle that ranges from 20 degrees to 60 degrees.

FIG. 10 illustrates a seventh embodiment, which differs from the fourth embodiment in that the side boundary surface 100′ is formed with a plurality of steps 104, and a number of the steps 104 is not less than three. A portion of the first surface 101 is included as being one of the steps 104. The steps 104 have an appearance of dark color demarcation lines. Each of the steps 104 has a width (L2) that ranges from 1 nm to 5000 nm, and in some embodiments, that ranges from 1 nm to 2000 nm. At least a portion of the steps 104 are roughened. The second semiconductor layer 120 has a relatively smooth sidewall, and the first semiconductor layer 110 has a relatively rough sidewall. The side boundary surface 100′ of the epitaxial structure 100 has an increase in roughness from an unroughened smooth surface to a coarsely roughened surface in a direction from the second surface 102 to the first surface 101 with roughened particles being arranged from small to large in size. A roughness of the steps 104 ranges from 0.1 μm to 0.2 μm, and a roughness of the second side boundary surface 100B′ is not greater than 0.1 μm.

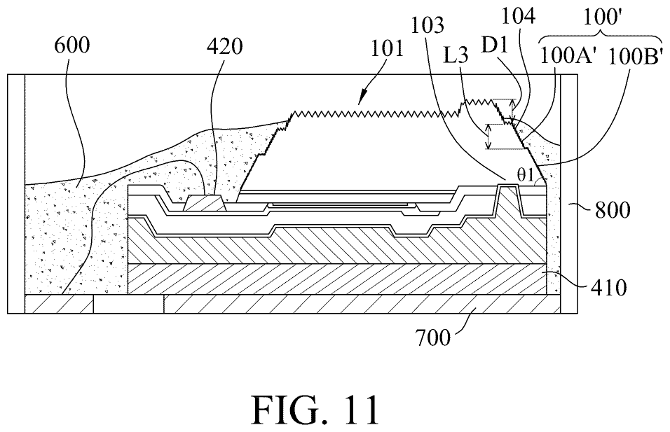

Referring to FIG. 11, in an eighth embodiment, a light-emitting device is shown, which includes a packaging substrate 700, an encapsulation material 600, and the LED similar to the seventh embodiment mounted on the packaging substrate 700 and covered by the encapsulation material 600. When the LED is packaged, the encapsulation material 600, such as white glue, is filled in a chamber 800. However, the encapsulation material 600 may creep on the LED and cover the light-exiting surface (i.e., the first surface 101), decreasing a light-exiting area of the LED.

When the epitaxial structure 100 of the LED is roughened, light extraction efficiency of the LED may be improved, which in turn improves the brightness of the LED. In a conventional light-emitting device, since a side surface of an epitaxial structure of a LED thereof is usually a continuous flat surface, roughening effects are unsatisfactory. In addition, when the encapsulation material is introduced into the chamber, the encapsulation material 600 is likely to creep on the LED and cover a light-exiting surface of the LED, adversely affecting the light-exiting efficiency of the conventional light-emitting device. Therefore, in this embodiment, the side boundary surface 100′ of the LED having the steps 104 is used to prevent the encapsulation material 600 from easily creeping on the light-exiting surface and to improve the light-exiting effect of the light-emitting device.

In this embodiment, the light-emitting device may further include a phosphor layer (not shown). The encapsulation material 600 may partially or completely cover the conductive substrate (i.e., the first electrode 410) of the LED, and in some embodiments, the encapsulation material 600 may at least partially cover the side boundary surface 100′ of the LED.

The first side boundary surface 100A′ is partially or completely roughened to provide a roughened structure. The roughened structure has a terrace-shaped configuration. The roughness of the first side boundary surface 100A′ is greater than the roughness of the second side boundary surface 100B′.

The number of the steps 104 of the terrace-shaped roughened structure may be two or more than three. Horizontal surfaces of the steps 104 can effectively prevent the encapsulation material 600 from creeping; the more the steps 104, the more the horizontal surfaces, and the effect of preventing the encapsulation material 600 from creeping up and covering the light-exiting surface of the LED is better when the encapsulation material 600 is filled in the chamber 800.

In this embodiment, the roughness of the terrace-shaped roughened structure ranges from 0.2 μm to 2 μm, and the roughness of the second side boundary surface 100B′ is not greater than 1 μm. The side boundary surface 100′ has an increase in roughness from an unroughened smooth surface to a coarsely roughened surface in the direction from the second surface 102 to the first surface 101 with roughened particles being arranged from small to large in size. The terrace-shaped roughened structure can effectively reduce total reflection loss and improve the light-exiting efficiency of the light-emitting device.

In some embodiments, an included angle (01) formed between the terrace-shaped roughened structure (i.e., the first side boundary surface 100A′) and an imaginary plane parallel to the second surface 102 ranges from 30 degrees to 50 degrees, such that not only the first surface 101 and the active layer 130 have sufficient areas for light extraction, but also the risk of the encapsulation material 600 creeping is reduced.

The greater the included angle (01), the more the number of the steps 104, and the more the horizontal surfaces, the better the effect of preventing the encapsulation material 600 from creeping up and covering the light-exiting surface of the LED.

It should be noted that, the width (L2) of each of the steps 104 is at least greater than 1 nm, so as to preventing the encapsulation material 600 from creeping.

Each of the steps 104 has a thickness (L3) ranging from 0.1 μm to 4 μm, or ranging from 4 μm to 10 μm. The smaller the thickness (L3), the more the number of the steps 104, and the more the horizontal surfaces, the better the effect of preventing the encapsulation material 600 from creeping up and covering the light-exiting surface of the LED.

The thicknesses (L3) of the steps 104 gradually decrease in the direction from the second surface 102 to the first surface 101 in a step manner; that is, the step 104 nearest the first surface 101 has the smallest thickness (L3).

The horizontal surfaces of the steps 104 can effectively prevent the encapsulation material 600 from creeping up the first surface 101, and the nearer the horizontal surfaces are positioned adjacent to the first surface 101, the better the effect of preventing the encapsulation material 600 from creeping up and covering the light-exiting surface of the LED. In some embodiments, a vertical distance (D1) from the surface of the step 104 nearest to the first surface 101 to the first surface 101 is not greater than 2 μm.

In some embodiments, the first surface 101 is roughened with the roughness that ranges from 0.5 μm to 2 μm; flat surfaces alternating with inclined surfaces on the first surface 101 increase the area of the first surface 101 (i.e., the light-exiting surface) and also increase the roughened area and a roughness density of the first surface 101, which effectively improves the light-exiting efficiency of the light-emitting device.

In some embodiments, the first type semiconductor layer 110 is made of a GaN-based material with a low temperature, the second type semiconductor layer 120 is made of a GaN-based material with a high temperature, and the active layer 130 is made of a gallium nitride material or an indium gallium nitride material.

In some embodiments, the roughened surfaces of the first side boundary surface 100A′, the second side boundary surface 100B′ and the first surface 101 include roughened particles that have irregular roughened shapes, regular spherical shapes, or roughened conical shapes.

In some embodiments, the encapsulation material 600 may cover the side boundary surface 100′ and even the light-exiting surface (i.e., the first surface 101) of the LED, and in this embodiment, by virtue of the steps 104 formed on the side boundary surface 100′ of the epitaxial structure 100, the encapsulation material 600 is prevented from creeping over the LED. A highest point of the encapsulation material 600 on the side boundary surface 100′ is not higher than the first surface 101 of the epitaxial structure 100, so that the encapsulation material 600 does not cover the light-exiting surface (i.e., the first surface 101) of the LED, and the area of the light-exiting surface will not decrease. In addition, the side boundary surface 100′ has an increase in roughness from an unroughened smooth surface to a coarsely roughened surface in the direction from the second surface 102 to the first surface 101 with roughness particles being arranged from small to large in size. The unroughened smooth surface may reduce abnormalities, such as light loss resulting from creeping of the encapsulation material 600.

A distance between the highest point of the encapsulation material 600 covering the side boundary surface 100′ and the first surface 101 of the epitaxial structure 100 is not smaller than 0.1 μm. The encapsulation material 600 is white glue which includes a resin, such as silicone resin, and commonly-used silicone resin may be transparent or has a white color. In this embodiment, the encapsulation material 600 is white silicone resin. The existing designs of light-emitting devices generally experience a phenomenon of resin creeping, for example, due to capillary action.

It should be noted that, in this embodiment, a height of the second electrode 420 is lower than a height of the epitaxial structure 100, but in other embodiments, the height of the second electrode 420 may be higher than the height of the epitaxial structure 100, and the encapsulation material 600 not creeping on the second electrode 420 is ensured.

In other embodiments of the disclosure, at least the side boundary surface 100′ of the epitaxial structure 100 is covered with a protection layer (not shown), which has an effect of preventing the encapsulation material 600 from creeping. The protection layer has a refractive index that is smaller than a refractive index of the epitaxial structure 100, which is beneficial to light exiting from the side boundary surface 100′ of the LED. A material of the protection layer may include silicon dioxide, silicon nitride, aluminum oxide or any combinations thereof, and in this embodiment, the material of the protection layer is silicon dioxide. The protection layer has a thickness ranging from 100 Å to 20000 Å. In addition, instead of the epitaxial structure 100, the protection layer is roughened and terraced. In other embodiments, the vertical distance (D1) is not greater than 2 μm. By virtue of the buffering effect of the steps 104, the encapsulation material 600 is prevented from creeping on the first surface 101. In some embodiments, the distance between the highest point of the encapsulation material 600 covering the side boundary surface 100′ and the first surface 101 of the epitaxial structure 100 is greater than 0.1 μm.

In summary, the beneficial effects of the disclosure are as follows.

1. Since the recess 103 that is formed in the n-type hole region is opened at the side boundary surface 100′, manufacturing difficulties due to the limitation of the manufacturing platform are overcome, and the process window is enlarged.

2. By virtue of the configuration of the side boundary surface 100′ that is roughened, the reflective metal material of the first electrical connection structure 210 extending to the recess 103 of the n-type hole region is prevented from adversely affecting the photolithography process of the LED and from causing abnormal photolithographic etching; that is, light entering from the side boundary surface 100′ is prevented from reflecting to the photoresist on the surface of the LED chip, causing the photoresist to absorb undesirable light, which results in problems in etching, and a predetermined patterned structure cannot be acquired.

3. By virtue of the side boundary surface 100′ being roughened, the encapsulation material 600 is prevented from creeping on the first surface 101 (i.e., the light-exiting surface), and the light-exiting effect of the LED is not affected.

In the description above, for the purposes of explanation, numerous specific details have been set forth in order to provide a thorough understanding of the embodiment(s). It will be apparent, however, to one skilled in the art, that one or more other embodiments may be practiced without some of these specific details. It should also be appreciated that reference throughout this specification to “one embodiment,” “an embodiment,” an embodiment with an indication of an ordinal number and so forth means that a particular feature, structure, or characteristic may be included in the practice of the disclosure. It should be further appreciated that in the description, various features are sometimes grouped together in a single embodiment, figure, or description thereof for the purpose of streamlining the disclosure and aiding in the understanding of various inventive aspects; such does not mean that every one of these features needs to be practiced with the presence of all the other features. In other words, in any described embodiment, when implementation of one or more features or specific details does not affect implementation of another one or more features or specific details, said one or more features may be singled out and practiced alone without said another one or more features or specific details. It should be further noted that one or more features or specific details from one embodiment may be practiced together with one or more features or specific details from another embodiment, where appropriate, in the practice of the disclosure.

While the disclosure has been described in connection with what is (are) considered the exemplary embodiment(s), it is understood that this disclosure is not limited to the disclosed embodiment(s) but is intended to cover various arrangements included within the spirit and scope of the broadest interpretation so as to encompass all such modifications and equivalent arrangements.

1. A light-emitting diode, comprising:
an epitaxial structure having a first surface, a second surface opposite to said first surface, and a side boundary surface formed between said first surface and said second surface, and including
a first type semiconductor layer, an active layer and a second type semiconductor layer that are sequentially arranged in a direction from said first surface to said second surface, said active layer being configured for emitting light;
a first electrical connection structure electrically connected to said first type semiconductor layer, and including a reflective metal material;
a second electrical connection structure electrically connected to said second type semiconductor layer;
a first insulation layer; and
a second insulation layer disposed between said first electrical connection structure and said second electrical connection structure, said first electrical connection structure and said second electrical connection structure being electrically isolated from each other by said second insulation layer;
wherein
said epitaxial structure is formed with at least one recess on said second surface, said at least one recess extending through said second type semiconductor layer, said active layer and a portion of said first type semiconductor layer, said at least one recess being formed near a periphery of said side boundary surface,
said first insulation layer is disposed in said recess and extends to said second surface,
said first electrical connection structure has a protrusion extending through said at least one recess, and electrically connected to said first type semiconductor layer, and
at least a portion of said side boundary surface positioned above said at least one recess has a roughened surface.

2. The light-emitting diode as claimed in claim 1, wherein said roughened surface of said at least a portion of said side boundary surface has an average particle size ranging from 0.05 μm to 2 μm.

3. The light-emitting diode as claimed in claim 1, wherein said at least one recess is opened at said side boundary surface and is continuously formed or is not continuously formed along said side boundary surface.

4. The light-emitting diode as claimed in claim 1, wherein when a dimension of a lateral side of said light-emitting diode is smaller than 500 μm, said at least one recess is continuously formed along said side boundary surface, and when said dimension of said lateral side is not smaller than 500 μm, said at least one recess is not continuously formed along said side boundary surface.

5. The light-emitting diode as claimed in claim 4, wherein when said at least one recess is not continuously formed along said side boundary surface, said at least one recess includes a plurality of spaced apart recesses, and said side boundary surface includes said first type semiconductor layer, said active layer, and said second type semiconductor layer.

6. The light-emitting diode as claimed in claim 4, wherein said side boundary surface is roughened to have said roughened surface and is formed with a first side boundary surface and a second side boundary surface, said first side boundary surface including said first type semiconductor layer, said second side boundary surface including said second type semiconductor layer, said first side boundary surface having an average roughness that is not smaller than an average roughness of said second side boundary surface.

7. The light-emitting diode as claimed in claim 6, wherein said first side boundary surface is higher than said second side boundary surface, said first side boundary surface and/or said second side boundary surface being inclined to an imaginary plane, which is perpendicular to said second surface, by an angle that ranges from 20 degrees to 60 degrees.

8. The light-emitting diode as claimed in claim 1, wherein said side boundary surface is roughened to have said roughened surface and is formed with a plurality of steps, and a number of said steps is not less than three.

9. The light-emitting diode as claimed in claim 8, wherein each of said steps has a width that ranges from 1 nm to 5000 nm.

10. The light-emitting diode as claimed in claim 8, wherein at least some of said steps are roughened, said side boundary surface of said epitaxial structure having an increase in roughness from an unroughened smooth surface to a coarsely roughened surface in a direction from said second surface to said first surface with roughened particles being arranged from small to large in size.

11. The light-emitting diode as claimed in claim 1, wherein a conductive substrate or an insulation substrate is disposed on a side of said second surface opposite to said first surface.

12. The light-emitting diode as claimed in claim 1, wherein:
said first type semiconductor layer, said active layer, or/and said second type semiconductor layer are made of a GaN-based material; and
said at least a portion of said side boundary surface is roughened by a single-stepped wet etching with KOH solution or NaOH solution.

13. The light-emitting diode as claimed in claim 1, wherein said first surface is a light-exiting surface, and a portion of said first surface is roughened.

14. The light-emitting diode as claimed in claim 13, wherein at least a portion of said first surface positioned straightforwardly above said at least one recess is roughened or patterned, said at least one recess has a cross section that is parallel to said second surface, and an area of said at least a portion of said first surface that is roughened or patterned is 120% of an area of said cross section of said at least one recess.

15. The light-emitting diode as claimed in claim 1, wherein a portion of said side boundary surface where said at least one recess exists includes said first type semiconductor layer, said first type semiconductor layer is an n-type semiconductor layer doped with silicon, and said second type semiconductor layer is a p-type semiconductor layer, said first type semiconductor layer having a growth temperature that is higher than a growth temperature of said second type semiconductor layer, said first type semiconductor layer growing faster than said second type semiconductor layer.

16. The light-emitting diode as claimed in claim 1, wherein one of or both of said first electrical connection structure and said second electrical connection structure include(s) a transparent conductive layer configured for ohmic contact.

17. The light-emitting diode as claimed in claim 1, wherein said protrusion of said first electrical connection structure is spaced apart from said side boundary surface by a distance not greater than 8 μm.

18. The light-emitting diode as claimed in claim 1, wherein said at least one recess is situated along a die cutting channel of said light-emitting diode.

19. The light-emitting diode as claimed in claim 1, wherein
a portion of said first insulation layer covers said at least one recess and is formed with an insulation hole to expose said first type semiconductor layer and let said protrusion of said first electrical connection structure to extend therethrough for electrically connecting said first type semiconductor layer, and
said first insulation layer partially covers and contacts said second surface, and uncovers a portion of said second type semiconductor layer for electrically connecting said second electrical connection structure.

20. The light-emitting diode as claimed in claim 1, wherein a roughened covering layer is disposed on said side boundary surface and is roughened to have said roughened surface.

21. A light-emitting device, comprising a packaging substrate, an encapsulation material, and said light-emitting diode as claimed in claim 1, said light-emitting diode being mounted on said packaging substrate and covered by said encapsulation material.
